(19) United States
(12) Patent Application Publication
(10) Pub. No.: US 2008/0023067 A1
(43) Pub. Date: Jan. 31, 2008

(54) Solar cell with nanostructure electrode

(76) Inventors: Liangbing Hu, Los Angeles, CA (US); George Gruner, Los Angeles, CA (US); David Hecht, Los Angeles, CA (US); Michael Rowell, Menlo Park, CA (US); Mark Topinka, Evanston, IL (US); Michael McGehee, Stanford, CA (US)

Correspondence Address: VENABLE LLP, P.O. BOX 34385, WASHINGTON, DC, 20043-9998, US

(21) Appl. No.: 11/698,995

(22) Filed: Jan. 29, 2007

Related U.S. Application Data
(63) Continuation-in-part of application No. PCT/US05/47315, filed on Dec. 27, 2005.
(60) Provisional application No. 60/833,845, filed on Jul. 28, 2006.

(51) Int. Cl. H01L 31/04; B05D 5/12; B82B 1/00; B82B 3/00

(52) U.S. Cl. 136/256; 427/74; 977/890; 977/932; 977/948

(57) ABSTRACT

An optoelectronic device comprising at least one nanostructure-film electrode and fabrication methods thereof are discussed. The optoelectronic device may further comprise a different material to fill in porosity in the nanostructure-film. Additionally, the optoelectronic device may be a solar cell, comprising at least one of a variety of photosensitive active layers.

### CROSS-REFERENCE TO RELATED PATENT APPLICATIONS

This application claims priority to U.S. Provisional Patent Application No. 60/833,845, filed Jul. 28, 2006, and entitled “ORGANIC SOLAR CELLS WITH CARBON NANOTUBE NETWORK ELECTRODES,” and PCT Application No. US/2005/047315, filed Dec. 27, 2005, and entitled “COMPONENTS AND DEVICES FORMED USING NANOSCALE MATERIALS AND METHODS OF PRODUCTION,” which are herein incorporated by reference.

### COPYRIGHT & TRADEMARK NOTICE

A portion of the disclosure of this patent document contains material that is subject to copyright protection. The owner has no objection to the facsimile reproduction by any one of the patent document or the patent disclosure, as it appears in the Patent and Trademark Office patent file or records, but otherwise reserves all copyrights whatsoever.

Certain marks referenced herein may be common law or registered trademarks of third parties affiliated or unaffiliated with the applicant or the assignee. Use of these marks is by way of example and shall not be construed as descriptive or limit the scope of this invention to material associated only with such marks.

### FIELD OF THE INVENTION

The present invention relates in general to solar cells, and more particularly to thin-film solar cells comprising at least one nanostructure-film.

### BACKGROUND

A solar cell is an optoelectric device that converts photons from the sunlight into electricity. Fundamentally, the device needs to photo-generate charge carriers (e.g., electrons and holes) in a photosensitive active layer, and separate the charge carriers to conductive electrodes that will transmit the electricity.

Historically, bulk technologies employing crystalline silicon (c-Si) have been used as the light-absorbing semiconductors in most solar cells, despite the fact that c-Si is a poor absorber of light and requires a high material thickness (e.g., hundreds of microns). However, the high cost of c-Si wafers has led the industry to research alternate, and generally less-expensive, solar cell materials.

Specifically, thin film solar cells can be created with relatively inexpensive materials on flexible surfaces. The selected materials are preferably strong light absorbers and need only be about a micron thick, thereby reducing materials costs significantly. Such materials include, but are not limited to, those based on silicon (e.g., amorphous, protocrystalline, nanocrystalline), cadmium telluride (CdTe), copper indium gallium selenide (CIGS), chalcogenide films of copper indium selenide (CIS), gallium arsenide (GaAs), light absorbing dyes, quantum dots, organic semiconductors (e.g., polymers and small-molecule compounds like polyphenylene vinylene, copper phthalocyanine and carbon fullerenes) and other non-silicon semiconductor materials. These materials are generally amenable to large area deposition on rigid (e.g., glass) or flexible (e.g., PET) substrates, with semiconductor junctions formed in various manners, such as a p-i-n device (e.g., with amorphous silicon) or a hetero-junction (e.g., with CdTe and CIS).

Regardless of the thin-film device architecture chosen, an at least semi-transparent conducting layer is required to form a front electrical contact of the cell, so as to allow light transmission through to the active layer(s). As used herein, a layer of material or a sequence of several layers of different materials is said to be “transparent” when the layer or layers permit at least 50% of the ambient electromagnetic radiation in relevant wavelengths to be transmitted through the layer or layers. Similarly, layers which permit some but less than 50% transmission of ambient electromagnetic radiation in relevant wavelengths are said to be “semi-transparent.”

Currently, the most commonly used transparent electrodes are transparent conducting oxides (TCOs), specifically indium-tin-oxide (ITO) on glass. However, ITO can be an inadequate solution for many emerging applications (e.g., non-rigid solar cells, due to ITO's brittle nature), and the indium component of ITO is rapidly becoming a scarce commodity. Moreover, deposition of transparent conducting oxides (TCOs) for minimal light loss normally requires a sputtering process, which can severely damage the underlying active layer(s).

Consequently, more robust and abundant transparent conductors are required not only for solar cell applications but for optoelectronic applications in general.

### SUMMARY OF INVENTION

The present invention provides an optoelectronic device comprising at least one nanostructure-film.

Nanostructure-films include, but are not limited to, network(s) of nanotubes, nanowires, nanoparticles and/or graphene flakes. Specifically, transparent conducting nanostructure-films composed of randomly distributed single-wall nanotubes (SWNTs) (i.e., networks thereof) have been demonstrated as substantially more mechanically robust than ITO. Additionally, SWNTs can be deposited using a variety of low-impact methods (e.g., it can be solution processed), and comprise carbon, which is one of the most abundant elements on Earth. Nanostructure-films, according to embodiments of the present invention, were demonstrated as having sheet resistances of less than 300 Ω/square with at least 90% optical transmission of 550 nm light.

An optoelectronic device according to an embodiment of the present invention is preferably a solar cell comprising a photosensitive active layer sandwiched between a first electrode and a second electrode, wherein at least one of the first and second electrodes comprises a network of nanostructures (e.g., a nanostructure-film). Active layers compatible with the present invention may include, but are not limited to, those based on silicon (e.g., amorphous, protocrystalline, nanocrystalline), cadmium telluride (CdTe), copper indium gallium selenide (CIGS), chalcogenide films of copper indium selenide (CIS), gallium arsenide (GaAs), light absorbing dyes, quantum dots, organic semiconductors (e.g., polymers and small-molecule compounds like polyphenylene vinylene, copper phthalocyanine and carbon fullerenes) and other non-silicon semiconductor materials. These materials are generally amenable to large area deposition on rigid (e.g., glass) or flexible (e.g., PET) substrates, with semiconductor junctions formed in different ways, such as a p-i-n device (e.g., with amorphous silicon) or a hetero-junction (e.g., with CdTe and CIS).

A solar cell according to a further embodiment of the present invention may additionally incorporate a different material (e.g., a conducting polymer) that serves to fill pores in the nanostructure (e.g., SWNT) network. The different material may be a polymer, and may be mixed with nanostructures prior to deposition (e.g., to form a composite), and/or may be deposited separately (e.g., and allowed to diffuse into the nanostructure network).

Other features and advantages of the invention will be apparent from the accompanying drawings and from the detailed description. One or more of the above-disclosed embodiments, in addition to certain alternatives, are provided in further detail below with reference to the attached figures. The invention is not limited to any particular embodiment disclosed.

### BRIEF DESCRIPTION OF THE DRAWINGS

The invention is better understood from reading the following detailed description of the preferred embodiments, with reference to the accompanying figures in which:

FIGS. 1A-1D are schematic representations of optoelectronic devices according to embodiments of the present invention.

FIG. 2 shows the sheet resistance versus transmittance for nanotube films produced according to an embodiment of the present invention.

FIG. 3 shows atomic force microscope (AFM) images of SWNT network films 3A before and 3B after PEDOT:PSS deposition and annealing.

FIG. 4 shows the current density-voltage characteristics of an organic solar cell according to an embodiment of the present invention under AM 1.5 G conditions.

FIG. 5 graphs the optical transmission of a PEDOT binder-carbon nanotube network for light of given wavelengths.

FIG. 6 illustrates several nanostructure deposition methods that are compatible with embodiments of the present invention.

FIG. 7 is a flowchart outlining a fabrication method according to embodiments of the present invention.

Features, elements, and aspects of the invention that are referenced by the same numerals in different figures represent the same, equivalent, or similar features, elements, or aspects in accordance with one or more embodiments of the system.

### DETAILED DESCRIPTION OF THE PREFERRED EMBODIMENTS

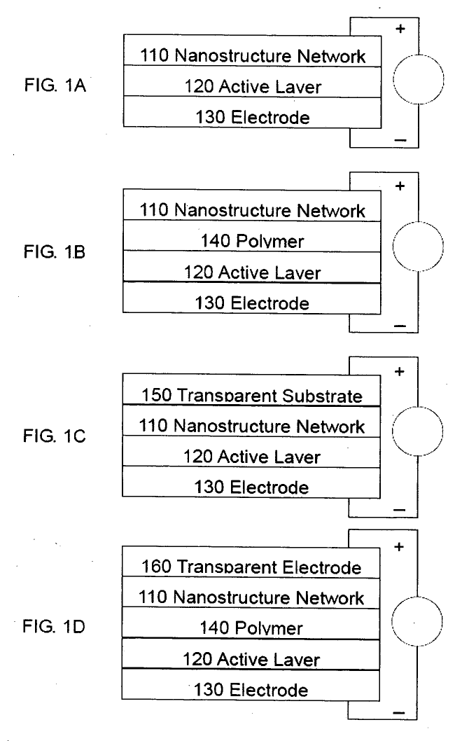

Referring to FIG. 1A, an optoelectronic device according to an embodiment of the present invention comprises a nanostructure network 110, an active layer 120 and an electrode 130. This device may be a solar cell, which is a semiconductor device that converts photons from the sun (solar light) into electricity. Fundamentally, the device needs to photo-generate charge carriers (e.g., electrons and holes) in an active layer, and separate the charge carriers to a conductive electrode that will transmit the electricity.

The active layer 120 is preferably a strong light absorber such as, for example, one based on silicon (e.g., amorphous, protocrystalline, nanocrystalline), cadmium telluride (CdTe), copper indium gallium selenide (CIGS), chalcogenide films of copper indium selenide (CIS), gallium arsenide (GaAs), light absorbing dyes, quantum dots, organic semiconductors (e.g., polymers and small-molecule compounds like polyphenylene vinylene, copper phthalocyanine and carbon fullerenes) and other non-silicon semiconductor materials. These materials are generally amenable to large area deposition on rigid (e.g., glass) or flexible (e.g., PET) substrates, with semiconductor junctions formed in different ways, such as a p-i-n device (e.g., with amorphous silicon) or a hetero-junction (e.g., with CdTe and CIS).

The nanostructure network 110 may form a nanostructure-film, and may comprise, but is not limited to, nanotubes, nanowires, nanoparticles and/or graphene flakes. It is preferably at least semi-transparent so as to allow light transmission through to underlying active layer(s), and electrically conductive so as to collect separated charges (e.g., holes) from the underlying active layer (e.g., as an anode). As used herein, a layer of material or a sequence of several layers of different materials is said to be “transparent” when the layer or layers permit at least 50% of the ambient electromagnetic radiation in relevant wavelengths to be transmitted through the layer or layers. Similarly, layers which permit some but less than 50% transmission of ambient electromagnetic radiation in relevant wavelengths are said to be “semi-transparent.”

The electrode 130 is also preferably electrically conductive so as to collect separated charges (e.g., electrons) from the active layer (e.g., as a cathode). This electrode needs not be transparent, and may comprise a conventional metal conductor (e.g., aluminum).

Referring to FIG. 1B, a solar cell according to another embodiment of the present invention further comprises a different material, e.g., a polymer 140, between the active layer 120 and nanostructure network 110. This polymer is, preferably, electrically conductive 110. Additionally or alternatively, this polymer may serve as a passivation material (e.g., a fluoropolymer) and/or encapsulant.

The polymer 140 may be deposited separately, and/or may be mixed with nanostructures and deposited as a composite layer. For example, SWNTs can be dispersed in aqueous solution and sonicated for a period of time, then mixed with an aqueous solution containing a conducting polymer. The mixture can then be sonicated and spin-coated onto a substrate, with the resulting film subsequently cured over a hotplate. Additionally or alternatively, a nanostructure network may be first deposited on a substrate, with a conducting polymer solution subsequently deposited onto the nanostructure network and allowed to freely diffuse.

In a preferred embodiment, the nanostructure network comprises SWNTs and the conducting polymer comprises PEDOT:PSS. Other suitable conducting polymers may include, but are not limited to, ethylenedioxythiophene (EDOT), polyacetylene and poly(para phenylene vinylene) (PPV). The combination of different transparent and conducting layers can be used to optimize parameters such as the work function of the layer. The composite layer may additionally contain conducting nanoparticles to be used as resins for increasing the viscosity of nanostructure solutions.

In one experiment, a poly(3,4-ethylenedioxythiophene):poly(styrene sulfonate) (PEDOT:PSS) solution deposited onto a nanostructure network comprising single walled carbon nanotubes (SWNTs) reduced electrode sheet resistance by about 20% (e.g., to about 160 Ω/square). Given that the same PEDOT:PSS film (95 nm thick) spun on glass (i.e., with no nanostructures) had a sheet resistance of 15 kΩ/square, the above drop in sheet resistance cannot be attributed merely to parallel conduction. Rather, the reduction in electrode sheet resistance may be attributed to a reduction in sheet resistance between conducting SWNTs (e.g., by filling a plurality of pores in the network) and/or doping of semiconducting SWNTs in the network.

Referring to FIGS. 1C and 1D, a solar cell according to additional embodiments of the present invention may further comprise a transparent substrate 150. The substrate 150 may be rigid or flexible, and may comprise, for example, glass, polyethylene terephthalate (PET), polyethylene naphthalate (PEN), polycarbonate (PC), polyethersulfone (PES) and/or Arton.

Nanostructure network(s) 110 may be deposited on the substrate 150 through a variety of techniques such as, for example, spraying, drop-casting, dip-coating and transfer printing, which are discussed in greater detail below.

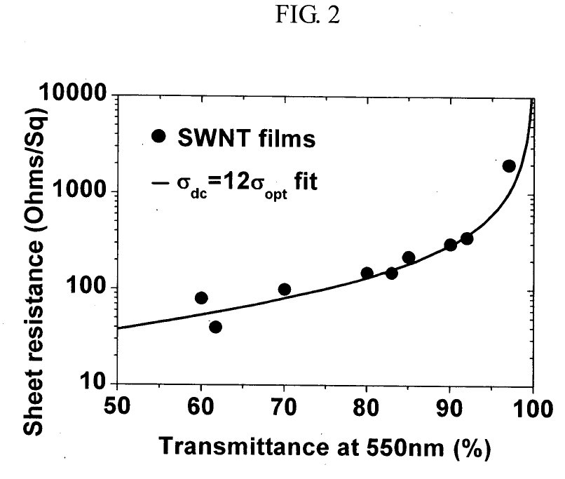

Referring to FIG. 2, a sheet resistance versus transmittance graph evidences the performance of nanostructure-films produced according to embodiments of the present invention, wherein the nanostructures are SWNTs. As in most materials, thicker films have a lower sheet resistance (i.e., higher electrical conductivity) and transmittance (i.e., less light can pass through a thicker material) than thinner films. Nanostructure film performance can be tailored to given device requirements by, for example, increasing or decreasing film thickness to attain desired transmittance and electrical conductivity.

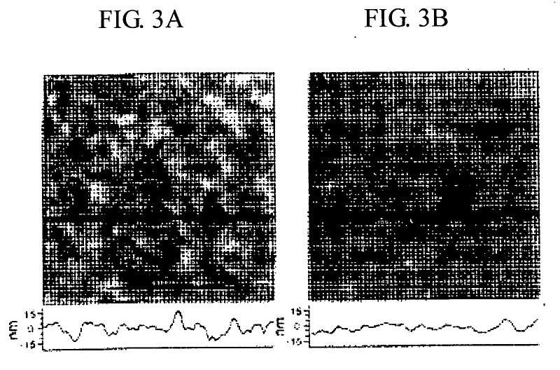

Referring to FIG. 3, atomic force microscope (AFM) images show nanostructure-films produced according to an embodiment of the present invention 3A before and 3B after PEDOT:PSS deposition and annealing. The nanostructure-films comprise a network(s) of SWNTs, and display remarkable uniformity.

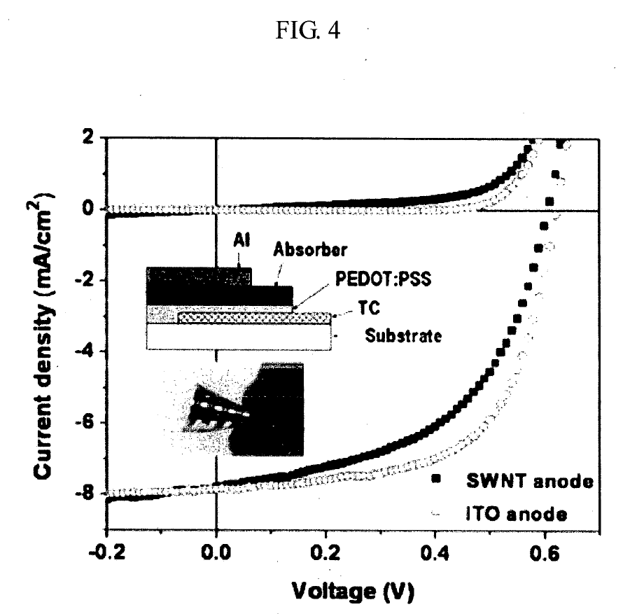

Referring to FIG. 4, a nanostructure-film electrode solar cell according to an embodiment of the present invention (e.g., using films similar to those imaged in FIG. 3) displayed performance comparable to more-conventional ITO electrode solar cells. In the tested device, the organic active layer comprised P3HT:PCBM and the nanostructure-film electrode comprised a flexible SWNT network(s) (e.g., on PET) as an anode. Current density-voltage characteristics were plotted against a control device employing a P3HT:PCBM active layer and an ITO (e.g., on glass) anode. Under AM 1.5 G conditions, the devices fabricated using SWNT network(s) operated almost identically to those using ITO coated glass.

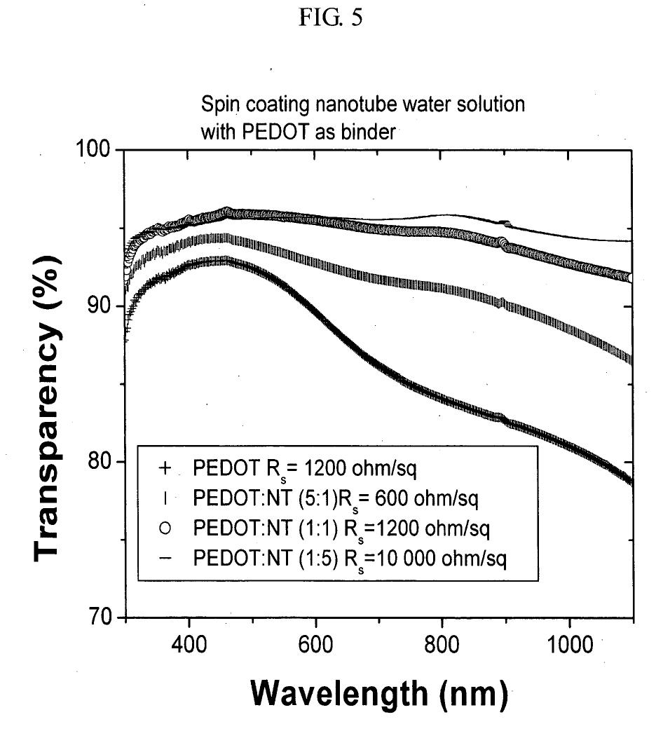

Referring to FIG. 5, an optical transmission graph of a PEDOT binder-SWNT network demonstrates the viability of the nanostructure networks of the present invention for optoelectronic applications.

To fabricate this exemplary sample, water soluble arc-discharged nanotube powder from Carbon Solutions Inc. was first dispersed in distilled oxide (DI) water by bath sonication. Nanotube solution and PEDOT:PSS (Baytron F. HC) in water were then mixed together in different proportions. The resulting mixture was subsequently bath-sonicated again.

The solution was then spin-coated onto a pre-cleaned glass slide at a speed of 1000 rpm, and cured over a hotplate. The transmittance and sheet resistance of the films was measured and plotted in FIG. 5.

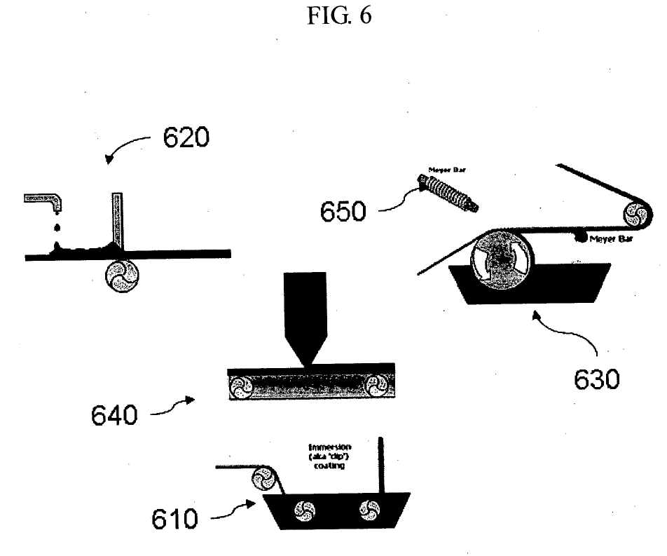

Referring to FIG. 6, in addition to spin-coating with a conductive polymer binder, a nanostructure solution/film may be deposited onto a substrate using a number of different methods. Various methods for fabricating and depositing nanostructure networks are described in PCT application US/2005/047315, entitled “Components and Devices Formed Using Nanoscale Materials and Methods of Production.” Those and other deposition methods include, but are not limited to, spray coating, dip coating 610, drop coating 620 or casting, slot die coating, micro-gravure printing, roll coating 630 and/or inkjet printing 640. A Meyer rod 650 may be used to squeeze the solutions for a more uniform nanostructure solution coating.

Additionally or alternatively, nanostructures may be deposited using a transfer stamping method. For example, commercially available SWNTs (e.g., produced by arc discharge) may be dissolved in solution with surfactants and then sonicated. The well dispersed and stable solutions may then be vacuum filtered over a porous alumina membrane. Following drying, the SWNT films may be lifted off with a poly(dimethylsiloxane) (PDMS) stamp and transferred to a flexible poly(ethylene terephthalate) (PET) substrate by printing.

This method has the added advantage of allowing deposition of patterned films (e.g., where the PDMS stamp is already patterned). Other compatible patterning methods include, but are not limited to, photolithography/etching and liftoff (e.g., using photoresist or toner).

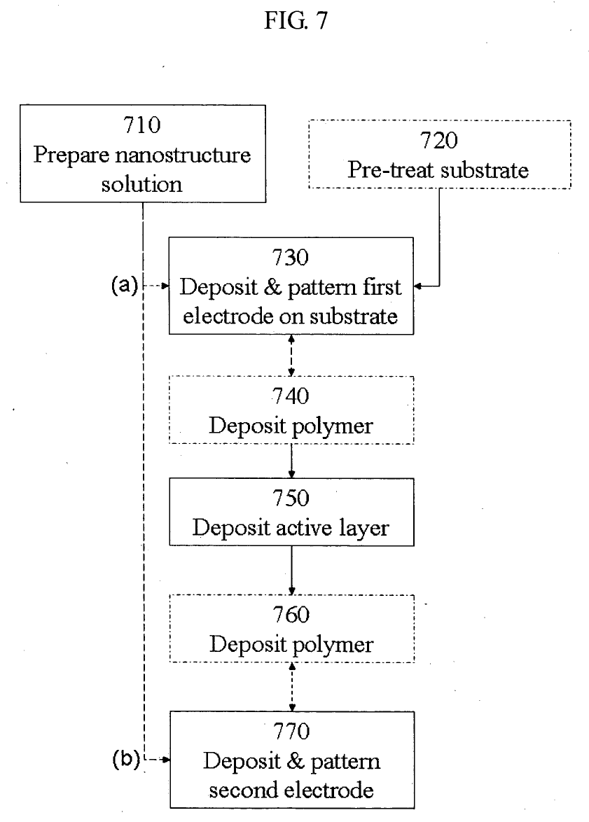

Referring to FIG. 7, a method for fabricating solar cells according to above-described and other embodiments of the present invention is provided. This method comprises preparing a nanostructure solution 710 and pre-treating a substrate 720. The latter step may be omitted depending on the types of substrates and surfactants used. For example, transparent substrates such as PET, PEN, polycarbonate, or glass do not generally require pretreatment if Triton-X is used as a surfactant.

In an exemplary embodiment of the present invention, the nanostructure solution may be prepared by dispersing water soluble arc-discharged nanotube powder from Carbon Solutions Inc. in distilled oxide (DI) water by bath sonication. This solution may further be mixed with a different conductive material (e.g., a conductive polymer binder such as PEDOT:PSS) at this stage to form a composite.

The solar cell begins to take shape when the first electrode is deposited and patterned (patterning is optional), for example, on the substrate 730. The nanostructure-film may be patterned before (e.g., using PDMS stamp transfer), during (e.g., using a lift-off technique) or after (e.g., using photolithography and etching) deposition. The substrate is preferably transparent, but does not need to be for all embodiments and/or applications.

In a preferred embodiment, the first electrode is an anode comprising a nanostructure network. The nanostructures comprising the network are preferably SWNTs (solubilized in step 710 following (a)), which may be deposited by such methods as those described in connection with FIG. 6.

For example, the substrate may be dipped into the nanostructure solution, the former having been either treated or matched with an appropriate surfactant such that a layer of solution coats the substrate surface. The solvent may then be evaporated from the solution using, e.g., a linear heating bar or infrared laser. Additionally, solvent evaporation may be aided by air-flow blow drying.

Where a surfactant is used, the substrate will preferably undergo a subsequent wash to remove surfactant from the dried nanostructure-film on the substrate. Washing may comprise rinsing the film with water, and then drying it with air-flow blow dry or heat. Other rinsing agents can be used, e.g., methanol.

Additionally or alternatively, the first electrode may comprise a composite material of nanostructures and, for example, a conductive polymer binder. Such composites may be sonicated and spin-coated onto a substrate, with the resulting film subsequently cured over a hotplate.

In another example, a nanostructure network is first deposited on a substrate 730, and a conducting polymer solution is then deposited 740 onto the nanostructure network and allowed to freely diffuse. Alternatively, the polymer may be deposited 740 before the nanostructure network 730. Preferably, although the different conducting material is deposited separately, it will fill a plurality of pores in the adjacent nanostructure network.

For example, in one experiment, a 30-nm-thick SWNT network film (T=85%, Rs=200 Ω/square) deposited on a poly(ethylene terephthalate) (PET) flexible substrate was coated with a PEDOT:PSS by spin-casting and then heating the substrate. Consistent results were obtained when either the PEDOT:PSS solution was applied on the surface and let free to diffuse several minutes before the spin-coating operation in order to fill in open porosity of the SWNT film or when a PEDOT:PSS/isopropanol 1:1 mix was used to improve the wetting.

Once the first electrode 730 and optional polymer material 740 are deposited on the substrate, an active layer may be deposited onto the first electrode and/or different conducting material. Preferably, the active layer is photosensitive and may be based on silicon (e.g., amorphous, protocrystalline, nanocrystalline), cadmium telluride (CdTe), copper indium gallium selenide (CIGS), chalcogenide films of copper indium selenide (CIS), gallium arsenide (GaAs), light absorbing dyes, quantum dots, organic semiconductors (e.g., polymers and small-molecule compounds like polyphenylene vinylene, copper phthalocyanine and carbon fullerenes) and other non-silicon semiconductor materials.

In an exemplary embodiment, an organic active layer is deposited by transferring a PET substrate coated with a 30-nm-thick SWNT film and a PEDOT:PSS layer with low roughness to an inert glove box where a solution of MDMO-PPV/PCBM in a 1:4 weight ratio or P3HT/PCBM in a 1:0:8 weight ratio (10 mg P3HT/mL) in chlorobenzene was spin-cast at 700 rpm.

In another exemplary embodiment, thin silicon active layers are deposited on a transparent substrate (e.g., glass) by chemical vapor deposition (CVD). For example, amorphous silicon may be deposited using hot-wire chemical vapor deposition (CVD) (e.g., decomposing silane gas (SiH₄) using a radiofrequency discharge in a vacuum chamber) or alternatively may sputter deposited (e.g., using ZnO/Ag). Nanocrystalline silicon may also be deposited effectively by hot-wire CVD (e.g., using a high hydrogen dilution (H₂/SiH₄=166), a high gas pressure of 2 Torr, and a high power-density of 1.0 W/cm2 at a low substrate temperature of 70° C.). Similarly, protocrystalline silicon may be deposited using photo-assisted CVD (e.g., employing alternate H₂ dilution under continuous ultraviolet (UV) light irradiation).

In yet another exemplary embodiment, a cadmium telluride active layer (CdTe) is deposited, possibly with a corresponding cadmium sulphide (CdS) layer, using close-space sublimation (CSS) (e.g., based on the reversible dissociation of the materials at high temperatures: 2CdTe(s)=Cd(g)+Te₂(g)). Alternatively, physical vapour deposition (PVD), CVD, chemical bath deposition and/or electrodeposition may be used.

In still another exemplary embodiment, copper-indium-gallium-selinide (CIGS) may be deposited using a rapid thermal annealing and anodic bonding process. Thermal annealing processes are also compatible with copper-indium-selinide (CIS) systems, the parent systems for CIGS.

In additional exemplary embodiments, gallium arsenide (GaAs) solar cells may be fabricated from epilayers grown directly on silicon substrates by atmospheric-pressure metal organic chemical vapor deposition (MOCVD); and active layers comprising quantum dots, (e.g., suspended in a supporting matrix of conductive polymer or mesoporous metal oxide) may be fabricated by growing nanometer-sized semiconductor materials on various substrates (e.g., using beam epitaxy on a semi-insulating GaAs(100) substrate).

After the active layer is deposited, another optional conductive material may be deposited 760. Preferably, this material is deposited when the second electrode comprises a nanostructure network.

Finally, a second electrode may be deposited 770 to complete the basic device architecture. In said first embodiment, this second electrode (e.g., cathode) needs not be transparent, and thus may comprise a conventional metal (e.g., aluminum) deposited using known techniques. Note, electrode layers may often be deposited directly upon an active and/or polymer layer (e.g., without the use of a substrate).

The present invention has been described above with reference to preferred features and embodiments. Those skilled in the art will recognize, however, that changes and modifications may be made in these preferred embodiments without departing from the scope of the present invention. These and various other adaptations and combinations of the embodiments disclosed are within the scope of the invention.

What is claimed is:

1. A solar cell, comprising:
a photosensitive active layer;
a first electrode; and
a second electrode, wherein at least one of the first and second electrodes comprises a network of nanostructures, and
wherein the active layer is disposed between the first and second electrodes.

2. The solar cell of claim 1, further comprising a different material, wherein the different material fills at least a plurality of pores in the network of nanostructures.

3. The solar cell of claim 2, wherein the nanostructures are single-walled carbon nanotubes (SWNTs).

4. The solar cell of claim 3, wherein the different material is a polymer, and
wherein the polymer forms a composite with the network of nanostructures.

5. The solar cell of claim 3, wherein the different material is a polymer, and
wherein the polymer is deposited separately from but in electrical contact with the network of nanostructures.

6. The solar cell of claim 1, wherein the network of nanostructures has a sheet resistance of less than 500 Ω/square and at least 80% optical transmission of 550 nm light.

7. The solar cell of claim 1, wherein the network of nanostructures has a sheet resistance of less than 400 Ω/square and at least 90% optical transmission of 550 nm light.

8. The solar cell of claim 1, wherein the network of nanostructures has a sheet resistance of less than 300 Ω/square and at least 90% optical transmission of 550 nm light.

9. The solar cell of claim 1, wherein the photosensitive active layer is based on an organic polymer.

10. The solar cell of claim 1, wherein the photosensitive active layer is based on at least one light absorbing dye.

11. The solar cell of claim 1, wherein the photosensitive active layer is based on CdTe.

12. The solar cell of claim 1, wherein the photosensitive active layer is based on CIGS.

13. The solar cell of claim 1, wherein the photosensitive active layer is based on CIS.

14. The solar cell of claim 1, wherein the photosensitive active layer is based on GaAs.

15. The solar cell of claim 1, wherein the photosensitive active layer is based on amorphous silicon.

16. The solar cell of claim 1, wherein the photosensitive active layer is based on protocrystalline silicon.

17. The solar cell of claim 1, wherein the photosensitive active layer is based on nanocrystalline silicon.

18. The solar cell of claim 1, wherein the photosensitive active layer is based on quantum dots.

19. A method of fabricating a solar cell, comprising:
preparing a nanostructure solution;
forming a first electrode;
depositing an active layer over the first electrode; and
depositing a second electrode over the active layer, wherein at least one of the first and second electrodes comprises a network of nanostructures, and
wherein the network of nanostructures is fabricated from the nanostructure solution.

20. The method of claim 19, further comprising depositing a different material, wherein the different material is a polymer, and
wherein the polymer fills at least a plurality of pores in the network of nanostructures.
